(19) United States
(12) Patent Application Publication
(10) Pub. No.: US 2009/0279275 A1
(43) Pub. Date: Nov. 12, 2009

(54) METHOD OF ATTACHING AN INTEGRATED CIRCUIT CHIP TO A MODULE

(76) Inventors: Stephen Peter Ayotte, Bristol, VT (US); David J. Hill, Richmond, VT (US); Timothy M. Sullivan, Essex, VT (US)

Correspondence Address: SCHMEISER, OLSEN & WATTS, 22 CENTURY HILL DRIVE, SUITE 302, LATHAM, NY, 12110, US

(21) Appl. No.: 12/118,145

(22) Filed: May 9, 2008

(51) Int. Cl. H05K 7/02; H01L 21/60

(52) U.S. Cl. 361/808; 438/118; 29/879; 257/E21.506

(57) ABSTRACT

A method of attaching an integrated circuit chip to a module and a resultant structure. The method includes placing a solder bump tape between the chip and the module, the solder bump tape including an array of solder columns embedded in a dielectric sheet; aligning and contacting top surfaces of solder columns with respective chip pads of an array of chip pads of the chip and aligning and contacting bottom surfaces of the solder columns with respective module pads of an array of module pads; and reflowing the solder columns to form solder interconnections between chip pads and respective module pads.

### FIELD OF THE INVENTION

The present invention relates to the field of integrated circuit packaging; more specifically, it relates to a method and structure for electrically and mechanically connecting integrated circuit chips to modules.

### BACKGROUND OF THE INVENTION

A common technology for electrically attaching integrated circuit chips to modules is variously called flip-chip attachment, controlled collapse chip connection (C4) attachment and solder bump attachment. In this technology, solder columns are formed on pads on the integrated circuit chip and then the chip is placed on a module so the solder bumps are sitting on corresponding pads. The solder bumps are then heated so they melt (reflow) and physically and electrically connect the chip pads to the module pads. Then a dielectric underfill material is injected between the module and integrated circuit chip, filling the space between solder bumps. This technology has some limitations, which include, voids in the underfill, chip tilting during reflow and missing solder bumps (particularly with low-lead and non-lead solder) to name a few. These limitations can impact yield and reliability and require several testing and inspection steps be included in the manufacturing process adding to cost and turn-around time. Accordingly, there exists a need in the art to overcome the deficiencies and limitations described hereinabove.

### SUMMARY OF THE INVENTION

A first aspect of the present invention is a method of attaching an integrated circuit chip to a module, comprising: placing a solder bump tape between the integrated circuit chip and the module, the solder bump tape including an array of solder columns embedded in a dielectric sheet, top surfaces of the solder columns exposed at a top surface of the dielectric sheet and bottom surfaces of the solder columns exposed at a bottom surface of the dielectric sheet; aligning and contacting top surfaces of the solder columns with respective chip pads of an array of chip pads of the integrated circuit and aligning and contacting bottom surfaces of the solder columns with respective module pads of an array of module pads of the module; and reflowing the solder columns to form solder interconnections between chip pads of the array of chip pads and respective module pads of the array of module pads.

A second aspect of the present invention is a structure, comprising: an underfill comprising a dielectric sheet between a dielectric top adhesive layer and a dielectric bottom adhesive layer; an integrated circuit chip having an array of chip pads disposed on a top surface thereof, the top adhesive layer bonded to the top surface of the integrated circuit chip between chip pads of the array of chip pads; a module having an array of module pads disposed on a top surface thereof, the bottom adhesive layer bonded to the top surface of the module between module pads of the array of module pads; and solder interconnections extending from chip pads of the array of chip pads through the top adhesive layer, the dielectric sheet and the bottom adhesive layer to corresponding module pads of the array of module pads.

A third aspect of the present invention is a method of attaching an integrated circuit chip to a module, comprising: placing a solder bump tape between a top surface of the integrated circuit chip and a top surface of the module, the solder bump tape including an array of solder columns embedded in a dielectric sheet, a top surface of the dielectric sheet facing the top surface of the integrated circuit chip and a bottom surface of the dielectric sheet facing the top surface of the module, opposite top and bottom surfaces of the solder columns proximate respectively to the top and bottom surfaces of the dielectric sheet not covered by the dielectric sheet; aligning and contacting top surfaces of solder columns of the array of solder columns with respective chip pads of an array of chip pads disposed on the top surface of the integrated circuit and aligning and contacting bottom surfaces of solder columns of the array of solder columns with respective module pads of an array of module pads disposed on the top surface of the module; and reflowing the solder columns to form solder interconnections between chip pads of the array of chip pads and respective module pads of the array of module pads.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is an exploded cross-sectional/side view of the components of a integrated circuit package according to embodiments of the present invention;

FIG. 2 is a top view of a solder bump tape according to embodiments of the present invention;

FIG. 3 is an exploded cross-sectional/side view of assembly of a integrated circuit package according to embodiments of the present invention;

FIG. 4 is a top view of alternative solder bump tape(s) according to embodiments of the present invention;

FIG. 5 is cross-sectional view of a first type of solder bump tape according to embodiments of the present invention;

FIG. 6 is cross-sectional view of a second type of solder bump tape according to embodiments of the present invention;

FIG. 7 is cross-sectional view of a third type of solder bump tape according to embodiments of the present invention;

FIG. 8 is cross-sectional view of a fourth type of solder bump tape according to embodiments of the present invention;

FIG. 9 is cross-sectional view of a fifth type of solder bump tape according to embodiments of the present invention;

FIG. 10 is cross-sectional view of a sixth type of solder bump tape according to embodiments of the present invention;

FIG. 11 is cross-sectional view of a seventh type of solder bump tape according to embodiments of the present invention;

FIG. 12 is an exploded detailed cross-sectional/side view of the components of a integrated circuit package according to embodiments of the present utilizing solder bump tape having protruding solder columns; and

FIG. 13 is an exploded detailed cross-sectional/side view of the components of a integrated circuit package according to embodiments of the present utilizing solder bump tape using recessed solder columns.

### DETAILED DESCRIPTION OF THE INVENTION

An integrated circuit module is first level packaging element intermediate between an integrated circuit chip and a second level packaging element. Examples of module types include ceramic modules (wires on or embedded in a ceramic substrate), multilayer ceramic modules (multiple levels of wires on and/or embedded in multiple layers of ceramic material) and printed circuit modules. Examples of second level packages include but are not limited to printed circuit boards and cards. Printed circuit boards/card and printed circuit modules may include one or more wiring levels embedded in and/or on one or more surfaces of an organic based dielectric material (which may include non-organic materials like fiberglass).

A lead-free interconnect is defined as metallurgical interconnect containing none to less than about 0.01% lead. A low lead interconnect is defined as a metallurgical interconnect containing less than about 5% lead. When heated, solder reacts with metallic pads to form electrically conductive alloy junctions that also serve to mechanically attach the solder to the metallic pad.

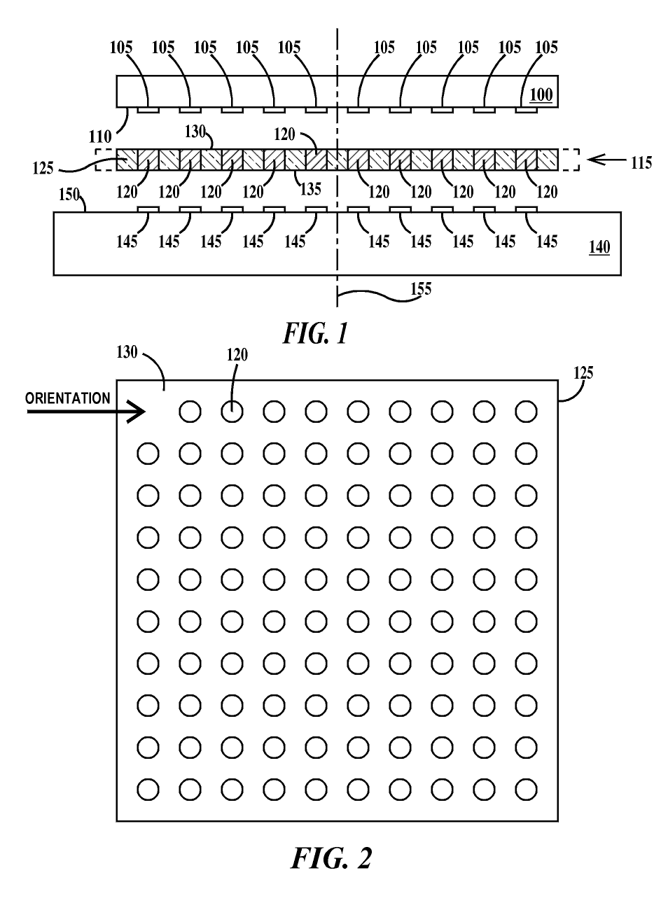

FIG. 1 is an exploded cross-sectional/side view of the components of an integrated circuit package according to embodiments of the present invention. In FIG. 1, the components of a integrated circuit package include (i) and integrated circuit chip 100 having electrically conductive chip pads 105 disposed on a top surface 110 of the integrated circuit chip, (ii) a solder bump tape 115, including solder columns 120 embedded in a dielectric sheet 125, the solder columns exposed at top and bottom surfaces 120 and 135 of the dielectric sheet, and (iii) a module 140, having module pads disposed on a top surface 150 of the module. Top surface 110 of integrated circuit chip is facing top surface 130 of dielectric sheet 125 and top surface 150 of module 140 is facing bottom surface 135 of dielectric sheet 125. Integrated circuit chip 100, solder bump tape 115 and module 140 are aligned along a vertical axis 155, so solder columns 120 are aligned to corresponding chip pads 105 and module pads 155.

In one example, solder columns 120 comprise a lead free solder. In one example solder columns 120 comprise a low-lead solder. In one example, solder column 120 comprise a mixture of two or more metals selected from the group consisting of tin, copper, silver, bismuth, indium, zinc and antimony. In one example, solder columns 120 comprise a material selected from the group consisting of a mixture of lead and tin, a mixture of tin and silver, a mixture of tin and copper, a mixture of tin and bismuth, a mixture of tin and zinc, a mixture of tin and indium, a mixture of tin and antimony, and a mixture of tin, silver and copper.

In one example dielectric sheet 125 comprises a material selected from the group consisting of epoxy, silica filled epoxy, silicone, acrylic resin, poly vinyl chloride resin, a thermosetting resin and a thermoplastic resin.

While in FIG. 1, the perimeter of solder bump tape 115 aligns with the perimeter of integrated circuit chip 100, it should be understood that the size (e.g., footprint) of solder bump tape 115 may be larger then that of integrated circuit chip 100 so the perimeter of solder bump tape 125 may extend past the perimeter of integrated circuit chip 100 on all or some of the sides of the integrated circuit chip as illustrated by the dashed lines.

FIG. 2 is a top view of a solder bump tape according to embodiments of the present invention. In FIG. 2, solder columns 120 are arranged in an exemplary 10 by 10 array that would correspond. Optionally, one position of the array (indicated by the arrow) has no solder column as an orientation guide for orienting the tape, chip and module during assembly. Corresponding chip and module pads positions would also be empty (have no pad in that position).

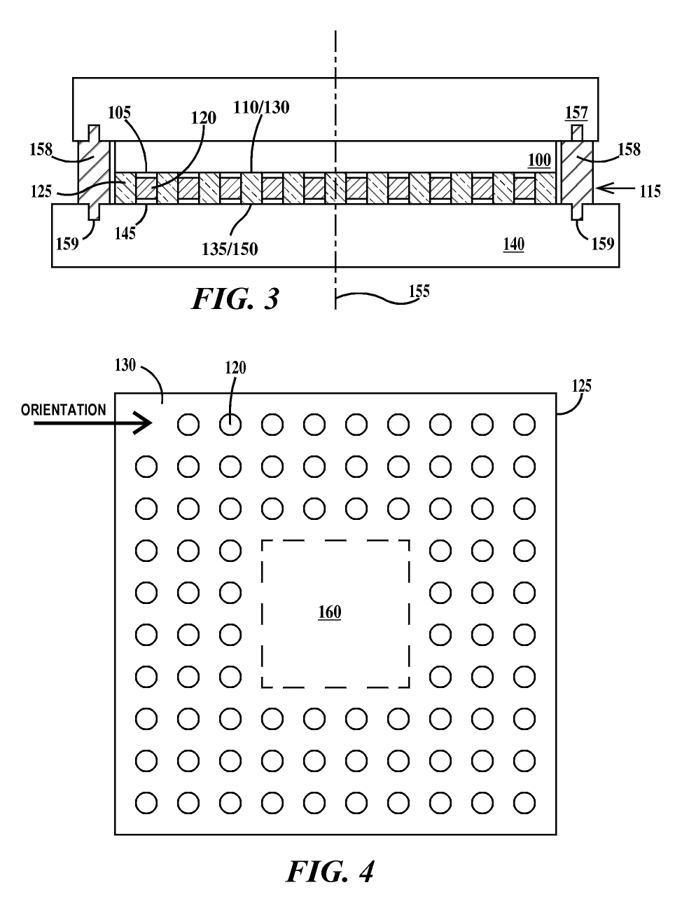

FIG. 3 is an exploded cross-sectional/side view of assembly of an integrated circuit package according to embodiments of the present invention. In FIG. 3, top surface 110 of integrated circuit chip 100 and top surface of 130 of dielectric sheet 125 are brought in contact, as are top surface 150 of module 140 and bottom surface 135 of dielectric sheet 125. Simultaneously, the surfaces of solder columns 120 proximate to top surface 130 of dielectric sheet 125 are brought into contact with corresponding chip pads 105 and the surfaces of solder columns 120 proximate to bottom surface 135 of dielectric sheet 125 are brought into contact with corresponding module pads 145. Then solder columns 120 are reflowed to form a solder connection, which is both an electrical connection and a physical connection, between chip pads 105 and module pads 145. Reflow may be accomplished by thermal heating in a furnace in an inert atmosphere or by ultrasonic heating. At the same time, dielectric sheet 125 forms a bond to top surface 110 of integrated circuit chip 100 and a bond to top surface 150 of module 140. Dielectric sheet, my further cure (e.g., cross-link) during the reflow process.

As an aid to bonding a plate 156 may be placed on a bottom surface 157 of integrated circuit chip 100 to press the stack consisting of integrated circuit chip 100, solder bump tape 115 and module 140 together during reflow. As an aid to alignment of chip pads 105, module pads 145 and solder columns 125, pins 158 that fit into holes 159 in module 140 may be employed. Either only plate 157 or pins 158 may be used, or both plate 158 and pins 159 may be used. Other alignment devices and methods of pressing the stack together may be used as well. In the event that the perimeter of solder bump tape 125 extends past the perimeter of integrated circuit chip 100, notches may be provided so dielectric sheet 125 does not touch pins 158.

FIG. 4 is a top view of alternative solder bump tape(s) according to embodiments of the present invention. In FIG. 4, a central region 160 of dielectric sheet 125 either contains no solder bumps (in this example a 3 by 3 array is missing) or region 160 may comprise an opening in the dielectric sheet (i.e., a region where there are no solder bumps 120 or dielectric material).

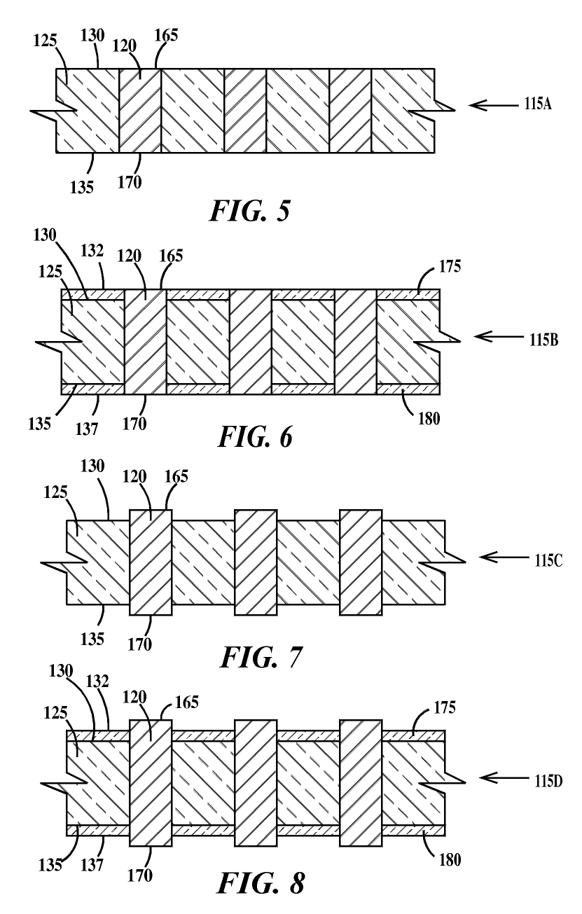

FIG. 5 is cross-sectional view of a first type of solder bump tape 115A, according to embodiments of the present invention. In FIG. 5, top surface 130 of dielectric sheet 125 is essentially coplanar with top surfaces 165 of solder columns 120 and bottom surface 135 of dielectric sheet 125 is essentially coplanar with bottom surfaces 170 of solder columns 120.

FIG. 6 is cross-sectional view of a second type of solder bump tape 115B according to embodiments of the present invention. In FIG. 6, a dielectric top adhesive layer 175 is formed on top surface 130 of dielectric sheet 125 and a dielectric bottom adhesive layer 180 is formed on bottom surface 135 of dielectric sheet 125. An exposed surface 132 of top adhesive layer 175 is essentially coplanar with top surfaces 165 of solder columns 120 and an exposed surface 137 of bottom adhesive layer 180 is essentially coplanar with bottom surfaces 170 of solder columns 120. In one example, adhesive layers 175 and are heat activated. In one example, dielectric sheet 125 comprises a fully cured material and adhesive layers 175 and 180 comprise a non-fully cured version of the same material as dielectric sheet 125. In one example, dielectric sheet 125 comprises a fully cured material and adhesive layers 175 and 180 comprise a non-fully cured material different from the material of dielectric sheet 125.

FIG. 7 is cross-sectional view of a third type of solder bump tape 115C according to embodiments of the present invention. In FIG. 7, top surfaces 165 of solder columns 120 extend past top surface 130 of dielectric sheet 125 and bottom surfaces 170 of solder columns 120 extend past bottom surface 135 of dielectric sheet 125.

FIG. 8 is cross-sectional view of a fourth type of solder bump tape 115D according to embodiments of the present invention. In FIG. 8, top adhesive layer 175 is formed on top surface 130 of dielectric sheet 125 and bottom adhesive layer 180 is formed on bottom surface 135 of dielectric sheet 125. Top surfaces 165 of solder columns 120 extend past exposed surface 132 of top adhesive layer 175 and bottom surfaces 170 of solder columns 120 extend past exposed surface 137 of bottom adhesive layer 180.

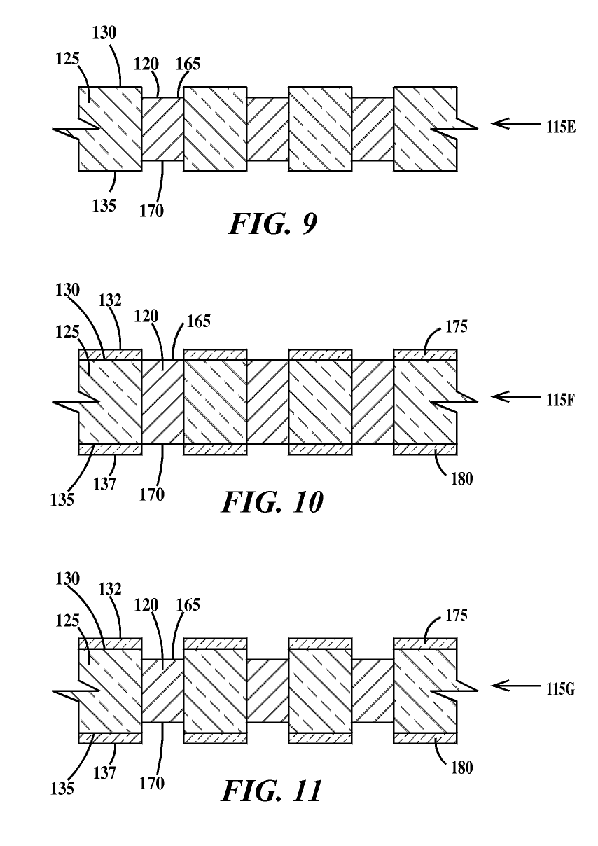

FIG. 9 is cross-sectional view of a fifth type of solder bump tape 115E according to embodiments of the present invention. In FIG. 9, top surfaces 165 of solder columns 120 are recessed below top surface 130 of dielectric sheet 125 and bottom surfaces 170 of solder columns 120 are recessed below bottom surface 135 of dielectric sheet 125.

FIG. 10 is cross-sectional view of a sixth type of solder bump tape 115F according to embodiments of the present invention. In FIG. 10, top adhesive layer 175 is formed on top surface 130 of dielectric sheet 125 and bottom adhesive layer 180 is formed on bottom surface 135 of dielectric sheet 125. Top surfaces 165 of solder columns 120 are recessed below exposed surface 132 of top adhesive layer 175 and bottom surfaces 170 of solder columns 120 are recessed below exposed surface 137 of bottom adhesive layer 137.

FIG. 11 is cross-sectional view of a seventh type of solder bump tape 115G according to embodiments of the present invention. In FIG. 11, top adhesive layer 175 is formed on top surface 130 of dielectric sheet 125 and bottom adhesive layer 180 is formed on bottom surface 135 of dielectric sheet 125. Top surfaces 165 of solder columns 120 are recessed below exposed surface 132 of dielectric sheet 125 and bottom surfaces 170 of solder columns 120 are recessed below bottom surface 135 of dielectric sheet 125.

Solder bump tapes 115A and 115B are examples of solder bump tapes having flush solder columns. Solder bump tapes 115C, 155D are examples of solder bump tapes having protruding solder columns. Solder bump tapes 115E, 115F and 115G are examples of solder bump tapes having recessed solder columns.

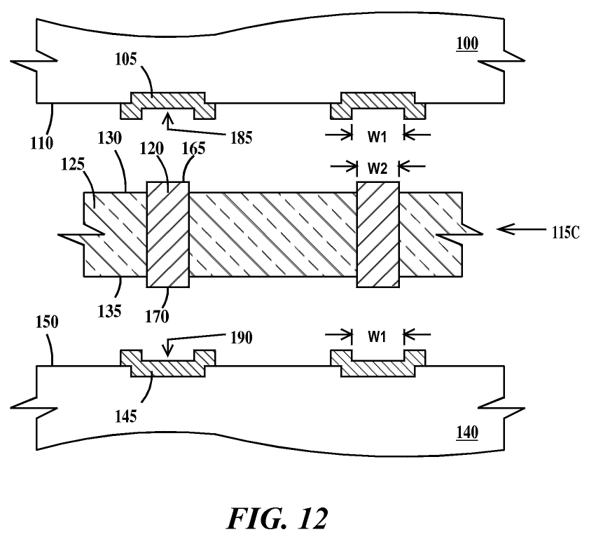

FIG. 12 is an exploded detailed cross-sectional/side view of the components of an integrated circuit package according to embodiments of the present utilizing solder bump tape having protruding solder columns. While FIG. 12 is illustrated with solder bump tape 115C, it should be understood that solder tape 115D of FIG. 8 may be substituted for solder bump tape 115C in FIG. 12. In FIG. 12, pads 105 of integrated circuit chip 100 include depressions 185 having a width W1 (either a diameter W1 or a square with sides W1). The width of solder columns 120 is W2 (either a diameter W2 or a square with sides W2), where W2 is less than W1. Pads 145 of module 140 include depressions 190 having width W1 (either a diameter W1 or a square with sides W1). When mechanically assembled, solder columns 125 fit into depressions 185 and 190 offering a degree of self alignment and also ensuring that there is sufficient solder in contact with pads 105 and 145 to ensure a low resistance solder joint after reflow.

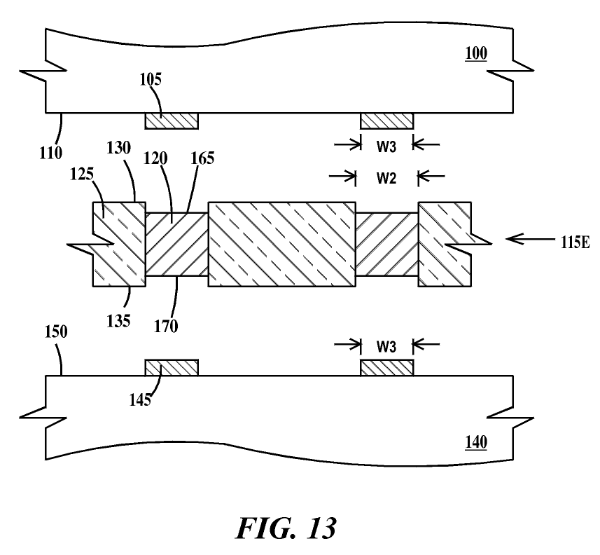

FIG. 13 is an exploded detailed cross-sectional/side view of the components of a integrated circuit package according to embodiments of the present utilizing solder bump tape using recessed solder columns. While FIG. 13 is illustrated with solder bump tape 115E, it should be understood that solder tape 115F of FIG. 9 or solder bump tape 116G of FIG. 11 may be substituted for solder bump tape 115E in FIG. 13. In FIG. 13, pads 105 of integrated circuit chip 100 have a width W3 (either a diameter W3 or a square with sides W3). The width of solder columns 120 is W2 (either a diameter W2 or a square with sides W2), where W3 is less than W2. Pads 145 of module 140 also have a width W3 (either a diameter W3 or a square with sides W3). When mechanically assembled, pads 105 and 145 extend past top and bottom surfaces of dielectric sheet 125 to contact top and bottom surfaces 165 and 170 respectively of solder columns 120 offering a degree of self alignment and also ensuring that there is sufficient solder in contact with pads 105 and 145 to ensure a low resistance solder joint after reflow.

Thus the embodiments of the present invention provide a one-step method of solder bump/underfill flip chip attachment of integrated circuit chips to modules that overcome the deficiencies and limitations described supra.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. For example, alternative solder bump tapes could one surface having one of flush, protruding or recessed solder columns and one surface having one surface having flush, protruding or recessed solder column, with the surfaces being different. Similarly, various combinations of surfaces with and without adhesive layers are possible. Therefore, it is intended that the following claims cover all such modifications and changes as fall within the true spirit and scope of the invention.

What is claimed is:

1. A method of attaching an integrated circuit chip to a module, comprising:
placing a solder bump tape between said integrated circuit chip and said module, said solder bump tape including an array of solder columns embedded in a dielectric sheet, top surfaces of said solder columns exposed at a top surface of said dielectric sheet and bottom surfaces of said solder columns exposed at a bottom surface of said dielectric sheet;
aligning and contacting top surfaces of said solder columns with respective chip pads of an array of chip pads of said integrated circuit and aligning and contacting bottom surfaces of said solder columns with respective module pads of an array of module pads of said module; and
reflowing said solder columns to form solder interconnections between chip pads of said array of chip pads and respective module pads of said array of module pads.

2. The method of claim 1, after said reflowing, said top surface of said dielectric sheet is bonded to a top surface of said integrated circuit chip and said bottom surface of said dielectric sheet is bonded to a top surface of said module.

3. A structure, comprising:
an underfill comprising a dielectric sheet between a dielectric top adhesive layer and a dielectric bottom adhesive layer;
an integrated circuit chip having an array of chip pads disposed on a top surface thereof, said top adhesive layer bonded to said top surface of said integrated circuit chip between chip pads of said array of chip pads;
a module having an array of module pads disposed on a top surface thereof, said bottom adhesive layer bonded to said top surface of said module between module pads of said array of module pads; and
solder interconnections extending from chip pads of said array of chip pads through said top adhesive layer, said dielectric sheet and said bottom adhesive layer to corresponding module pads of said array of module pads.

4. The structure of claim 3, wherein a perimeter of said integrated circuit chip is contained within a perimeter of said underfill.

5. A method of attaching an integrated circuit chip to a module, comprising:
placing a solder bump tape between a top surface of said integrated circuit chip and a top surface of said module, said solder bump tape including an array of solder columns embedded in a dielectric sheet, a top surface of said dielectric sheet facing said top surface of said integrated circuit chip and a bottom surface of said dielectric sheet facing said top surface of said module, opposite top and bottom surfaces of said solder columns proximate respectively to said top and bottom surfaces of said dielectric sheet not covered by said dielectric sheet;
aligning and contacting top surfaces of solder columns of said array of solder columns with respective chip pads of an array of chip pads disposed on said top surface of said integrated circuit and aligning and contacting bottom surfaces of solder columns of said array of solder columns with respective module pads of an array of module pads disposed on said top surface of said module; and
reflowing said solder columns to form solder interconnections between chip pads of said array of chip pads and respective module pads of said array of module pads.

6. The method of claim 5, wherein said top surfaces of said solder columns and said top surface of said dielectric sheet are coplanar and said bottom surfaces of said solder columns and said bottom surface of said dielectric sheet are coplanar.

7. The method of claim 5, wherein said top surfaces of said solder columns extend past said top surface of said dielectric sheet and said bottom surfaces of said solder columns extend past said bottom surface of said dielectric sheet.

8. The method of claim 5, wherein said top surfaces of said solder columns are exposed in a recess in said top surface of said dielectric sheet and said bottom surfaces of said solder columns are exposed in a recess in said bottom surface of said dielectric sheet.

9. The method of claim 5, wherein said solder bump tape further includes a dielectric top adhesive layer on said top surface of said dielectric sheet and a dielectric bottom adhesive layer on said bottom surface of said dielectric sheet and wherein said top surfaces of said solder columns and a top surface of said top adhesive layer are coplanar and said bottom surfaces of said solder columns and a top surface of said bottom adhesive layer are coplanar.

10. The method of claim 5, wherein said solder bump tape further includes a dielectric top adhesive layer on said top surface of said dielectric sheet and a dielectric bottom adhesive layer on said bottom surface of said dielectric sheet and wherein said top surfaces of said solder columns extend past a surface of said top adhesive layer furthest away from said top surface of said dielectric sheet and said bottom surfaces of said solder columns extend past a surface of said bottom adhesive layer furthest away from said bottom surface of said dielectric sheet.

11. The method of claim 5, wherein said solder bump tape further includes a dielectric top adhesive layer on said top surface of said dielectric sheet and a dielectric bottom adhesive layer on said bottom surface of said dielectric sheet and wherein said top surfaces of said solder columns are exposed in a recess in a surface of said top adhesive layer furthest away from said top surface of said dielectric sheet and said bottom surfaces of said solder columns are exposed in a recess in a surface of said bottom adhesive layer furthest away from said bottom surface of said dielectric sheet.

12. The method of claim 5, wherein said solder bump tape further includes a dielectric top adhesive layer on said top surface of said dielectric sheet and a dielectric bottom adhesive layer on said bottom surface of said dielectric sheet and wherein said top surfaces of said solder columns are exposed in a recess in said top surface of said dielectric sheet and said bottom surfaces of said solder columns are exposed in a recess in said bottom surface of said dielectric sheet.

13. The method of claim 5, wherein said solder columns extend past top and bottom surface of said solder bump tape, said chip pads include recesses into which said top surfaces of said solder columns fit during said contacting, and said module pads include recesses into which said bottom surfaces of said solder columns fit during said contacting.

14. The method of claim 13, wherein said solder bump tape further includes a dielectric top adhesive layer on said top surface of said dielectric sheet and a dielectric bottom adhesive layer on said bottom surface of said dielectric sheet, said top surface of said solder bump tape being a top surface of top adhesive layer and said bottom surface of said solder bump tape being a top surface of bottom adhesive layer.

15. The method of claim 5, wherein said solder columns are exposed in a recess in said top and bottom surface of said solder bump tape, top surfaces of said chip pads extending into a recess in a top surface of said solder bump tape during said contacting, and said module pads extending into a recess in a bottom surface of said solder bump tape during said contacting.

16. The method of claim 15, wherein said solder bump tape further includes a dielectric top adhesive layer on said top surface of said dielectric sheet and a dielectric bottom adhesive layer on said bottom surface of said dielectric sheet, said top surface of said solder bump tape being a top surface of top adhesive layer and said bottom surface of said solder bump tape being a top surface of bottom adhesive layer.

17. The method of claim 5, wherein said solder columns comprise a material selected from the group consisting of a mixture of lead and tin, a mixture of tin and silver, a mixture of tin and copper, a mixture of tin and bismuth, a mixture of tin and zinc, a mixture of tin and indium, a mixture of tin and antimony, and a mixture of tin, silver and copper.

18. The method of claim 5, wherein said dielectric sheet comprises a material selected from the group consisting of epoxy, silica filled epoxy, silicone, acrylic resin, poly vinyl chloride resin, a thermosetting resin and a thermoplastic resin.

19. The method of claim 5, wherein, after said reflowing, said top surface of said dielectric sheet is bonded to said top surface of said integrated circuit chip and said bottom surface of said dielectric sheet is bonded to said top surface of said module.

20. The method of claim 5, wherein said solder bump tape further includes a dielectric top adhesive layer on said top surface of said dielectric sheet and a dielectric bottom adhesive layer on said bottom surface of said dielectric sheet and after said reflowing, said top surface of said dielectric tape is adhesively bonded to said top surface of said integrated circuit chip by said top adhesive layer and said bottom surface of said dielectric tape is adhesively bonded to said top surface of said module by said bottom adhesive layer.
